(19) United States
(12) Patent Application Publication
(10) Pub. No.: US 2014/0103789 A1
(43) Pub. Date: Apr. 17, 2014

(54) Case With Interchangeable Back Plate

(71) Applicant: James L. Cox, III, Austin, TX (US)

(72) Inventor: James L. Cox, III, Austin, TX (US)

(21) Appl. No.: 13/933,424

(22) Filed: Jul. 2, 2013

Related U.S. Application Data
(63) Continuation-in-part of application No. 13/890,084, filed on May 8, 2013.
(60) Provisional application No. 61/713,155, filed on Oct. 12, 2012.
(60) Provisional application No. 61/713,155, filed on Oct. 12, 2012.
(60) Provisional application No. 61/823,165, filed on May 14, 2013.

(51) Int. Cl. H05K 5/02

(52) U.S. Cl. CPC H05K 5/02
USPC 312/280

(57) ABSTRACT

There are provided embodiments of a hand-holdable case sized and shaped to integrate a personal electronic device with other interchangeable articles or devices to conveniently allow the combination to be hand-held as one. In one exemplary embodiment the case provides resistance to wear and tear as well as drop protection for a portable electronic device and an interchangeable article or device. In another exemplary embodiment, the case includes a back plate that reversibly attaches to the personal electronic device case and secures an article or device such that the personal electronic device and article or device are easily carried as one, yet the article or device can be easily and reversibly detached and reattached to the personal electronic device case without unsheathing the personal electronic device.

### CROSS-REFERENCE TO RELATED APPLICATIONS

This application is related to Provisional Patent Application Ser. No. 61/713,155 filed 12 Oct. 2012 and non-Provisional patent application Ser. No. 13/890,084 filed 8 May 2013. This application is also related to Provisional Application Ser. No. 61/823,165 filed May 14, 2013; which are all incorporated by reference as if fully disclosed herein.

### II. FIELD OF THE TECHNOLOGY

The present disclosure relates to carrying cases, including protective cases that allow bundling with a personal electronic device, one or more other articles or devices, including communication devices and non-communication devices in a handheld form. The article or device is readily detachable and reattachable to the case yet secure when attached as a combination.

### III. SUMMARY OF A FEW ASPECTS OF THE INVENTION

This disclosure describes and illustrates cases for personal electronic devices. A case is sized and shaped to securely and aesthetically accommodate a personal electronic device. The case has a back, which may include a back plate, that has accommodations for the use of the personal electronic device that may include for example apertures for camera lenses, microphones, speakers, antennae, and the like, as determined by the particular personal electronic device secured or encased. Likewise the back face of the case, which may include or accommodate a back plate, may be shaped to include reliefs or protrusions, such as to accommodate batteries, memory, SIM cards, and so on. The back plate may mirror such reliefs or protrusions.

This disclosure also describes and illustrates back plates for protective cases for personal electronic devices where the back plate is configured to port one or more article or device. The back face of the case, which may include a back plate, has accommodations for the use of the personal electronic device. Those accommodations may include for example apertures, reliefs, or protrusions. The back includes structure or material that will conveniently and reversibly secure the case to another article or device. The back thus might include material that would adhere to magnetized material. The back plate likewise might be shaped to snap, reversible clip to, releasably latch to, connect, fasten, or reversibly lock to another device or article. The back plate could include a material such as one or more of the components of Velcro®, fibrillar adhesives, microfiber cloth, gecko materials, or adhesive materials, for example.

This disclosure also describes and illustrates articles and devices that can secure reversibly to the back face of a personal electronic device case. One such article is a protective plate that largely conforms to the surface contours of the back of the personal electronic device case. Such a plate could include one or more aperture to accommodate a camera lens, a microphone, a speaker, antennae, and the like, as determined by the particular personal electronic device protected. Another such article is a decorative plate or cover. Such could sport the texture or material of the user's choice. Such could also include material affiliative of a university, town, event, or team. Such could include photos, logos, flags, mascots, art, or patterns. The back plate could accommodate images, designs, woods, acrylics, or materials of the user's choice. Such a back plate thus might include material or he configured to reversibly adhere or attach to the personal electronic device case. The back plate could include material that would be drawn to magnetized material. The back plate likewise might be shaped to snap, reversible clip to, releasably latch to, connect, fasten, or reversibly lock to the personal electronic device case. The back plate could include a material such as one or more of the components of Velcro®, fibrillar adhesive, microfiber cloth, gecko materials, or adhesive materials, for example.

This disclosure also describes and illustrates articles and devices that can secure reversibly to the back face of a personal electronic device case, where such article or device has a utilitarian function. The article or device will thus reversibly mate to, couple to, and adhere to, a back plate. The personal electronic device and the reversibly detachable and reattachable article or device can be carried comfortably and conveniently as one. The personal electronic device and the reversibly detachable and reattachable article or device can be separated for the quick and convenient use of the article or device reversibly mated to, or adhered to, or coupled to the personal electronic device. The decoupling can be accomplished without unsheathing the personal electronic device from the protective case.

Thus, a back plate of a personal electronic device case would include material or be configured to reversibly adhere or attach to a utilitarian article or device, or in an alternative embodiment, to a case or attachment that could hold or secure that utilitarian device or article. The utilitarian device or article could include material or be configured such that it would mate with the back of the case. The utilitarian article or device might b drawn to magnetized material. The utilitarian article or device likewise might he shaped to snap, reversibly clip to, releasably latch to, connect, fasten, or reversibly lock to the back plate of the personal electronic device case. The utilitarian article or device or the case or attachment for securing or containing it could include a material such as one or more of the opposed adherent components of Velcro®, fibrillar adhesive, microfiber cloth, gecko materials, or material to which such adheres reversibly, for example.

As described hereafter, other aspects of these inventions exist, for example, in details of exemplary cosmetic and non-cosmetic product constructs, as well as the details of manufacture. Thus, the summary of a few aspects of the inventions is not to be interpreted as defining the inventions.

### IV. DESCRIPTION OF THE DRAWINGS

FIG. 1 is an exploded orthogonal view of an embodiment of the personal electronic device case showing a back plate in working relationship.

FIG. 2a is a front view of an embodiment of the personal electronic device case (reversibly detachable back plate not shown).

FIG. 2b is a back view of an embodiment of the personal electronic device case (reversibly detachable back plate not shown).

FIG. 2c is a back view of an embodiment of a back plate for a personal electronic device case.

FIG. 2d is a front view of an embodiment of a back plate for a personal electronic device case.

FIG. 2e is a side view of an embodiment of a personal electronic device case showing where one side forms an aperture to accommodate a personal electronic device (not shown) and having reversibly attachable back plate in place.

FIG. 2f is a side view of an embodiment of a personal electronic device case shown having reversibly attachable back plate in place.

FIG. 3 is an exploded orthogonal view of an embodiment of the personal electronic device case including the back plate and the attachable device in working relationship including in phantom a representative personal electronic device.

FIG. 4 is an orthogonal view of the front of an embodiment of the personal electronic device case with attached device in its environment.

FIG. 5 is a side view of the back plate and one side of an embodiment of the personal electronic device case with attached device in its environment showing through an aperture m the side a the as an exemplary personal electronic device.

FIG. 6 is a side view of a functional accessory detached from an embodiment of the personal electronic device case.

FIG. 7 is an exploded orthogonal view of a functional accessory detached from an embodiment of the personal electronic device.

### V. BACKGROUND

Personal electronic devices, also known as portable electronic devices, such as cellular phones, smart phones, tablets, laptop computers, palm pilots, eBook readers, Apple iPads and iPods, MP3 Players, pocket PC's, and similar products are particularly susceptible to receiving damage from being dropped, at least because they are many times per day picked up, set down, used, or mishandled. Protective cases have long been used for such personal electronic devices. The evolution in their design has focused on the protective aspects of such cases.

U.S. Pat. No. 4,294,496 to Murez discloses a hard outer metallic shell designed to protect a delicate computer screen and keyboard from damage that could result from folding the screen and keyboard against one another. While that may be effective, surrounding a personal electronic device with a hard metallic shell increases the time it takes for a user to access the personal electronic device and reduces response time. In addition, antidotal evidence suggests that weight, or rather the absence of it, is a key feature in the desirability of protective cases.

Marquet teaches in United States Application for Patent Publication No. 2009/0302799 a rigid case that substantially surrounds the entire body of the personal electronic device, but leaves the keyboard and screen exposed.

Ganhdi teaches in United States Application for Patent Publication No. 2010/0302716 a rigid case for a personal electronic device that extends beyond the edge of the screen to prevent the screen from being damaged if the personal electronic device falls.

Richardson teaches in U.S. Pat. No. 7,933,122 a case for a personal electronic device that has three layers: (1) a flexible inner membrane that holds the personal electronic device; (2) a hard shell cover; and (3) an outer flexible cushion.

McCarville in United States Application for Patent Publication No. 2013/0098788 filed 19 Oct. 2010 teaches the use of ferromagnetic materials mounted within it recess of the protective case to use for mounting. McCarville teaches that the protective case can be mounted to any magnet surface. McCarville envisions that such magnets could be conveniently coupled to a variety of surfaces, such as the dashboard of a car, a tabletop, a briefcase, a wall, or a portion of a user's clothing.

Specifically, McCarville describes in an exemplary embodiment, that the magnet is coupled to a surface using a permanent adhesive, such as double-sided tape or glue. In another embodiment, the magnet is coupled to a surface using a temporary coupling mechanism, such as a suction cup, a mating indent/detent, or a pair of magnets that wrap around the surface. In a preferred embodiment, where the ferromagnetic plate is located within a recess of the rear surface of the hard shell layer of the protective case, a portion of the magnet is sized and dimensioned to mate with that recess. Using a magnet as a back, the protective case can thus be reversibly attached to a portion of a user's clothing, by placing the front magnetic plate on a front surface of the thin material, and the rear magnetic plate on a rear surface of the thin material.

Protective cases such as those described above have been used on smartphones, sophisticated graphing scientific calculators, GPS devices, and satellite communication devices. Many people carry two or more of such devices. The need to carry two or more of such devices often results, paradoxically, in the need to carry a third device such as a purse, backpack, or briefcase to carry the smaller devices.

Switching between one personal electronic device and another increases the number of times any one personal electronic device must be set down, picked up, and balanced precariously. All of which leads to a greatly increased number of collisions with tabletops, running tracks, sidewalks, and elevator floors.

No product integrates a personal electronic device with a large number of interchangeable utilitarian devices in a case that is aesthetically suitable, protective, and convenient to carry.

The inventions illustrated and described and which are the subject of this application overcome all the problems set forth above. This application discloses embodiments of a hand-holdable case sized and shaped to integrate a personal electronic device with another article or device interchangeably in a form conveniently hand-held. The cases described or illustrated allow the combination of a personal electronic device and the interchangeable article to be carried simultaneously as one. In one exemplary embodiment, the interchangeable article is a protective back plate that can have particular value to the user because of personal, affiliative, or aesthetic considerations. In another exemplary embodiment, the personal electronic device case forms a sleeve to hold a smartphone and an interchangeable device, for example a satellite communications device. In another exemplary embodiment, the case has a back that reversibly adheres, mates, couples, or attaches to another utilitarian article or device so that the two are easily carried together. The interchangeable devices can be easily removed from and reunited with the case for use without unsheathing the personal electronic device.

### VI. DETAILED DESCRIPTION OF EXEMPLARY EMBODIMENTS

As used herein, unless the context dictates otherwise, terms such as “coupled,” “mated,” “adhered,” “attached” and so on mean and are intended to mean directly (in which two or more items are in contact with each other) and indirectly (in which at least one additional item is located between the at least two items). Therefore, terms such as “coupled to,” “mated to,” “attached to” and “adhered to” are used synonymously with “coupled with,” “mated with,” “attached with,' and “adhered with”, Preferably, such coupling, mating, adhering, and attaching are readily reversible and repeatable.

The discussion that follows describes any examples and embodiments of the inventive subject matter. Although each embodiment, represents a single combination of inventive elements, the inventive subject matter includes all possible combinations of the disclosed elements. Thus if one embodiment comprises elements A, B, and C, and a second embodiment comprises elements B and D, then the inventive subject matter is also considered to include other remaining combinations of A, B, C, or D, even if not explicitly disclosed.

Some aspects of carrying out the invention are described below as preferred embodiments with reference to the accompanied drawings, in which like features are indicated by like numerals.

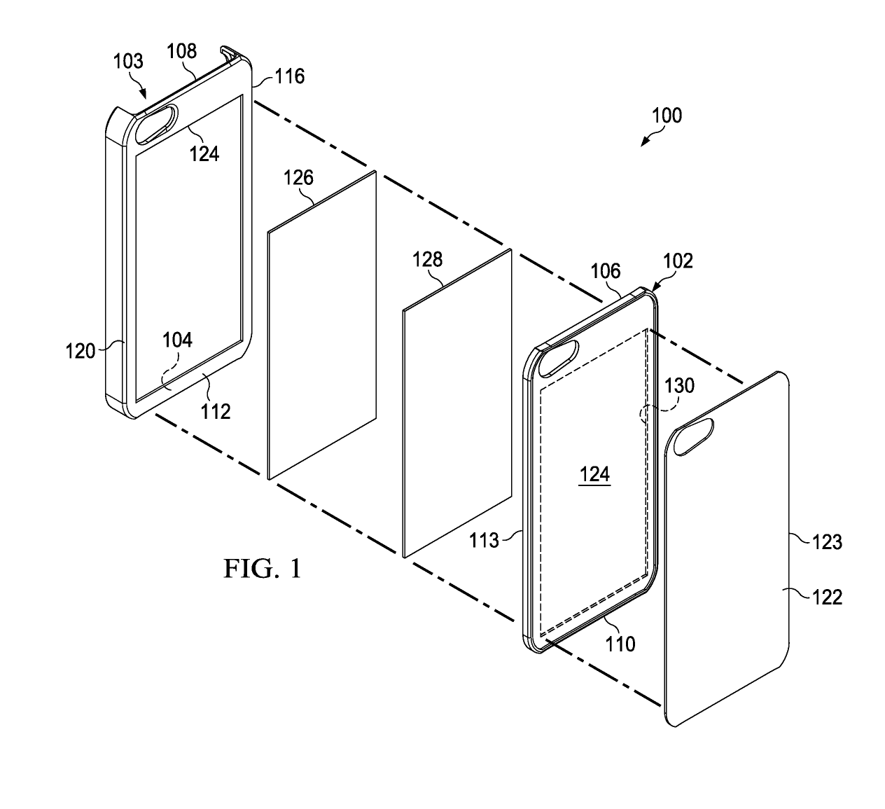

FIG. 1 is an exploded orthogonal view of an embodiment of the personal electronic device case 100 showing a detachable, interchangeable back plate 102 in its working relationship with the back face 104 of personal electronic device case 100. Back plate 102 is sized and shaped to conform to back face 104 of personal electronic device case 100. Thus, when back plate 102 is substantially flush against back face 104 of personal electronic device case 100, first minor edge 106 of back plate 102 is substantially parallel to first minor edge 108 of back face 104 of personal electronic device case 100. Likewise, when back plate 102 is substantially flush against, back face 104 of personal electronic device case 100, second minor edge 110 of back plate 102 is substantially parallel to second minor edge 112 of the back face 104 of personal electronic device case 100. When back plate 102 is substantially flush against back face 104 of personal electronic device case 100, first major edge 113 of back plate 102 is substantially parallel to first major edge 120 of the back face 104 of personal electronic device case 100. Likewise, when back plate 102 is substantially flush against back face 104 of personal electronic device case 100, second major edge 114 (hidden) of back plate 102 is substantially parallel to second major edge 116 of the back face 104 of personal electronic device case 100.

Continuing with FIG. 1, major exterior surface 122 of back plate 102 is shown substantially flat, meaning substantially two dimensional, without significant depression, relief, or variation in surface plane 123. Such an alternative embodiment is suited in particular for user involvement in choice of surface decoration, including the choice of surface material. Specifically, back plate 102 may be made having surface plane 123 having exterior surface 122 covered in any color or colors and in any too many materials, such as those that resemble copper, silver, gold, various common or exotic woods, carbon fiber, foam, rubber grip tape, mesh, textiles such as fabrics, wall papers, beads, tiles, leathers, hides, furs, and so on. Likewise, such an embodiment is amenable to the application of photographs, designs, and art provided by the user. Back plate 102 is designed to be relatively inexpensive to create using 3D printing, injection molding, or other fabrication techniques. As such, it is envisioned that organizations, fund-raising groups, teams, universities, artists and designers will produce a limitless variety if designs and patterns for surface plane 123 having exterior surface 122.

In another embodiment, surface plane 123 having exterior surface 122 may be raised or otherwise include contours. Such may enhance the ergonomics of the device or devices. Because personal electronic device case 100 is configured to reversibly and interchangeably mate with to variety of back plates 102, a variety of back plate configurations are provided for.

As also shown in the exploded orthogonal view of FIG. 1, back plate 102 can be interchangeable. Back plate 102 is reversibly detachable to back face 104 of personal electronic device case 100 using a variety of techniques. Protective case 100 is shown with a recess or cutout 124 in back face 104. Recess 124 can receive an insert 126 that can include material that could be magnetic or drawn to magnetized material. Thus, insert 126 could be metallic or magnetized. Correspondingly, insert 128 is configured to be placed in recess 130 (shown by dashed lines to represent the hidden face of back plate 102). Insert 126 and insert 128 can be retained in recess 124 and recess 130 using tension, friction, glue, mechanical fasteners, or otherwise. Likewise, insert 126 and insert 128 can be retained without the use of recesses. Insert 126 and insert 128 can include magnetic material, or one can include magnetic material and the other can include material attracted to a magnet.

In the exemplary embodiment of FIG. 1, personal electronic device case 100 can accommodate a communications device such as is smartphone sized to detachably connect to a smartphone. As shown in FIG. 1, in one preferred embodiment personal electronic device case 100 generally has six primary faces. As shown, in one preferred embodiment substantially the entire front face 103 (not shown) of personal electronic device case 100 is open to allow for the face of a device, for example a smartphone, to be accessible while the smartphone is placed with personal electronic device case 100.

Alternatively, back face 104 and back plate 102 can be configured to reversibly mate, couple, or adhere to each other by mechanical or other means. One or the other or both back face 104 or back plate 102 can be shaped to snap, or reversibly clip to, releasably latch to, connect., fasten, or reversibly lock to the other. Either of back face 104 or back plate 102, or both may include a material such as one of the components of Velcro®, fibrillar adhesive, microfiber cloth, gecko materials, or adhesive materials, for example.

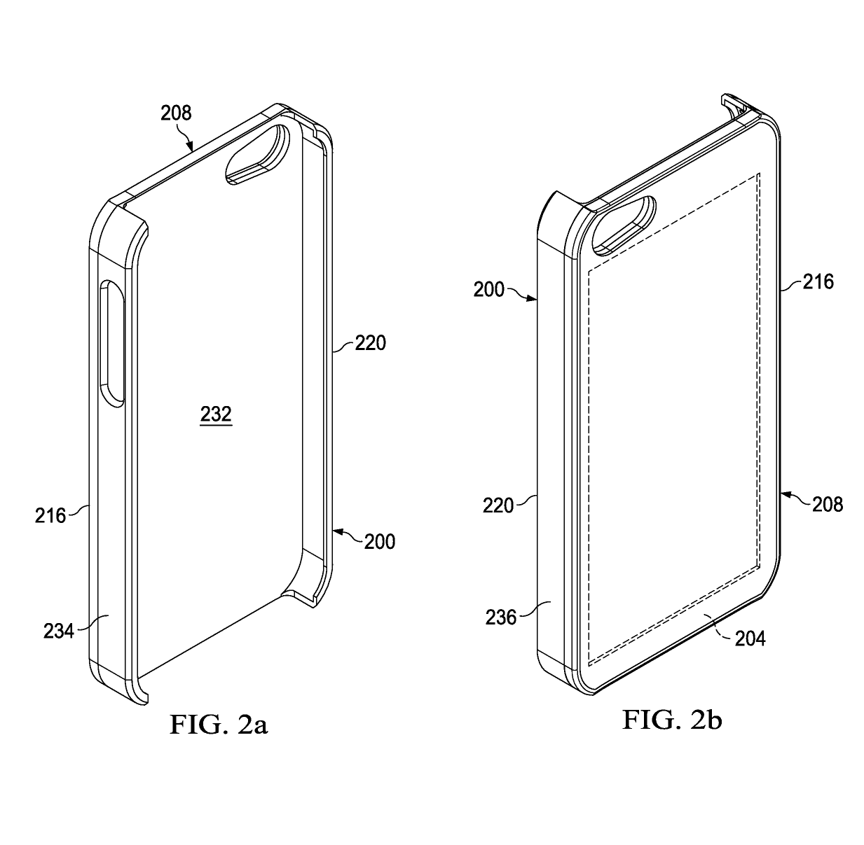

Turning now to FIG. 2, FIG. 2a is a front view of an embodiment of the personal electronic device case 200 with interior surface 232 of back face 204 exposed and opposed exterior surface 222 (hidden). There may be one to many planes and surfaces intercalated between interior surface 232 of back face 204 and exterior surface 222. In FIG. 2a, exterior surface 234 of major side 216 of personal electronic device case 200 faces the observer. The exterior surface 236 (hidden) of opposed major side 220 faces away from the observer in FIG. 2a, FIG. 2b is a back view of an embodiment of personal electronic device case 200 with a back plate. In FIG. 2b, exterior surface 236 of major side 220 is exposed to the observer as is back face 204 of back plate 208. FIG. 2c shows the interior surface 232 of personal electronic device case 200. Interior surface 232 could be adorned even though it typically would not be visible when personal electronic device case 200 is coupled with a personal electronic device such as a smartphone. FIG. 2d shows a back view of an embodiment of back plate 208 for a personal electronic device case 200. Such embodiments are well suited in particular for user involvement in the choice of surface decoration for exterior surface face 204. FIG. 2e is a side view of a personal electronic device case 200 showing where side surface 234 and side 216 form aperture 217 to accommodate a personal electronic device (not shown) and having an embodiment of back plate 208-in place. FIG. 2f is a side view of an embodiment of a personal electronic device case 200 also showing an embodiment of back plate 208 in place substantially flush with back face of personal electronic device case 200.

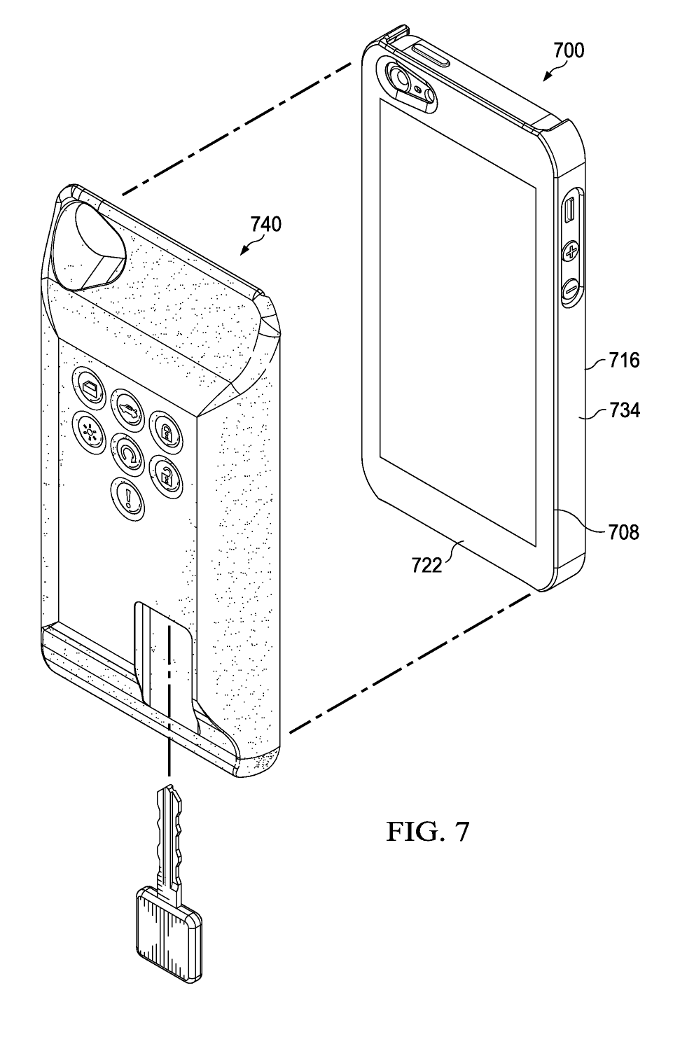

In accordance with an exemplary embodiment, back plate 208 can also he the side of an article or device, or can be configured to reversibly mate to, couple to, adhere to, or attach to an article or device including, for example, a mobile hot spot; a GoPro® video recorder; a paper notepad; a mini epinephrine pen; a inhaler; a vaporizer; a combination lock; a foldable eyeglasses case; a computer mouse; a finger pad; a Bluetooth® headset holder; an Apple iPod®; an MP3 player; a digital voice recorder; a shoulder rest; a GPS device; a satellite communication device; a compass; a whistle; at first aid kit; a data expansion pack; a video game controller; a laser pointer; access key card; cellular signal booster; full range AM/FM transmitter; a pedometer, an accelerometer; a speaker; a flash light; a digital scale; a thermostat; a key slot; a key ring; a toll tag; a pill compartment; a pen; a birth control compartment; an FM transmitter; a magnifying glass or plastic card; a GigaPet®, a card deck holder; a fan that circulates bug repellant or aromas; a baby monitor; a flash drive; a credit card reader; stylus; a fish eye lens; a heart rate monitor; a glucose meter with lancet and extra test strips; a blood pressure reader; a floating device designed to keep personal electronic device 200 afloat; a Wi-Fi® modem; a projector screen; a bottle opener; a battery pack; pepper spray; a makeup compartment; an Etch-A-Sketch®; a roller maze; a watch face; a compartment for, for example, a condom, coins, tickets, a tampon, earbuds, chapstick, lotion, sunscreen, utility tool, level, band aids, perfume or cologne, sanitizer, contact lenses, cigarettes, lighter, electric cigarettes, flask, breathalyzer, credit cards, business cards, gum, mints, or cough drops, measuring tape, mirror, money clip or a smart key (as shown in FIG. 7). All of the aforementioned items, as well as the following items could be attached to the personal electronic device as shown, for example, in FIG. 7.

The size, including width and height, as well as the configuration of reversibly attachable article or device (not shown) may vary depending on the shape and size of personal electronic device case 200. It is envisioned that back plate 208 will be available to accommodate different personal electronic devices of different sizes, including for example, smartphones, Apple iPads®, iPods®, laptop computers, and tablets.

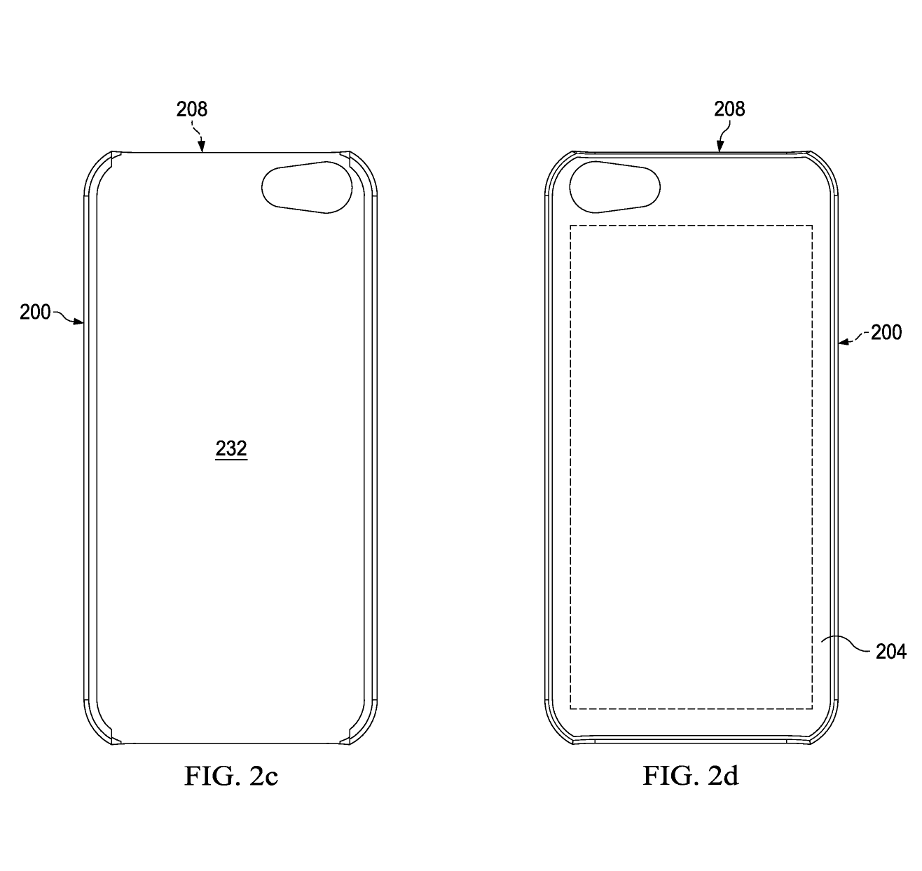

FIG. 3 is an exploded orthogonal environmental view of one embodiment of personal electronic device case 300. FIG. 3 shows one embodiment of detachable, interchangeable back plate 302 in its working relationship with back face 304 (hidden from the observer and not shown) of personal electronic device case 300. Back plate 302 is sized and shaped to conform to back face 304 of personal electronic device case 300. In the embodiment shown, detachable, interchangeable back plate 302 forms an aperture 336 sized and located to accommodate battery access for the device or article to be reversible attached to, mated to, coupled to, or adhered to personal electronic device 300 using back plate 302. Detachable, interchangeable back plate 302 in this embodiment forms aperture 336 sized and located to accommodate battery access cover 338 for use in reversibly attachable article or device 340, which as illustrated could be a satellite communication or GPS device.

As shown in the preferred embodiment of FIG. 3, back plate 302 is substantially flush against back face 304 of personal electronic device case 300. When back plate 302 is substantially flush against back face 304 of personal electronic device case 300, first minor edge 306 of back plate 302 is substantially parallel to first minor edge 308 of personal electronic device case 300. Likewise, when back plate 302 is substantially flush against back face 304 of personal electronic device 300, first minor edge 306 of back plate 302 is substantially parallel to first minor edge 342 of reversibly attachable article or device 340, which in FIG. 3 is a satellite communication or GPS device. When back plate 302 is substantially flush against back face 304 of personal electronic device case 300, second minor edge 310 of back plate 302 is substantially parallel to second minor edge 312 of the back face 304 of personal electronic device 300. Likewise, when back plate 302 is substantially flush against back side 304 of personal electronic device 300, second minor edge 310 of back plate 302 is substantially parallel to second minor edge 344 of reversibly attachable article or device 340.

When back plate 302 is substantially flush against back face 304 of personal electronic device case 300, first major edge 314 of back plate 302 is substantially parallel to first major edge 313 of the back face 304 of personal electronic device 300. Likewise back plate 302 is substantially flush against back face 304 of personal electronic device case 300, second major edge 318 of back plate 302 is substantially parallel to second major edge 315 of back face 304 of personal electronic device case 300. When back plate 302 is substantially flush against back face 304 of personal electronic device case 300, first major edge 314 of back plate 302 is substantially parallel to first major edge 346 of the reversibly attachable article or device 340.

As shown, personal electronic device case 300 can be secured to a personal electronic device for example by lip 305. Lip 305 can be configured to extend slightly from two or more faces such as the front face 303 or side faces 313 and 315 of personal electronic device case 300. Thus, side faces 313 and 315 may be used in his embodiment to hold reversibly attachable article or device 340 in place using lip 305. The intersections of each of such face help secure a smartphone or other device by personal electronic device case 300. Any slight flexibility of the material from which the personal electronic device case 300 is made allows for a smartphone or Other personal electronic device to be snapped in and out of personal electronic device case 300 with minimal force, but exerts sufficient restraining force to prevent the smartphone from falling from protective case 300 under its own weight or the magnitude of forces typically associated with normal operation of a personal electronic device.

Continuing with FIG. 3, major interior surface 322 (facing away from the observer in FIG. 3) of back plate 302 is shown as reversibly detachable to back face 304 of personal electronic device case 300 using a set of magnets 350. In this embodiment, the face of the reversibly attached article or device 340 becomes the major exterior surface. Although magnets 350 in one embodiment may comprise six disc and two bar magnets, the size, shape, strength and placement of magnets 350 may to some extent in some instances be a design or manufacturing choice. In other instances the size, shape, strength and placement of magnets 350 may be influenced by the identity and requirements of either the personal electronic device or the reversibly detachable article or device 340. Likewise, this disclosure includes magnets 350 as a component of back plate 302 with or without recesses therein to accommodate them.

In one preferred embodiment, back plate 302 can be configured to reversibly mate to, couple to, or adhere to or with device, or article 340 by physical or mechanical means, rather than by magnetic or electromechanical means. Back plate 302 can be shaped to snap, or reversibly clip to, releasably latch to, connect, fasten, or reversibly lock to article or device 340. Back plate 302, or article 340 may include a material such as one of the adherent components of Velcro®, fibrillar adhesive, microfiber cloth, gecko materials, or adhesive materials, for example. The magnets 350, or other means of securing the back plate 302 may be on the front or back side of the back plate 302.

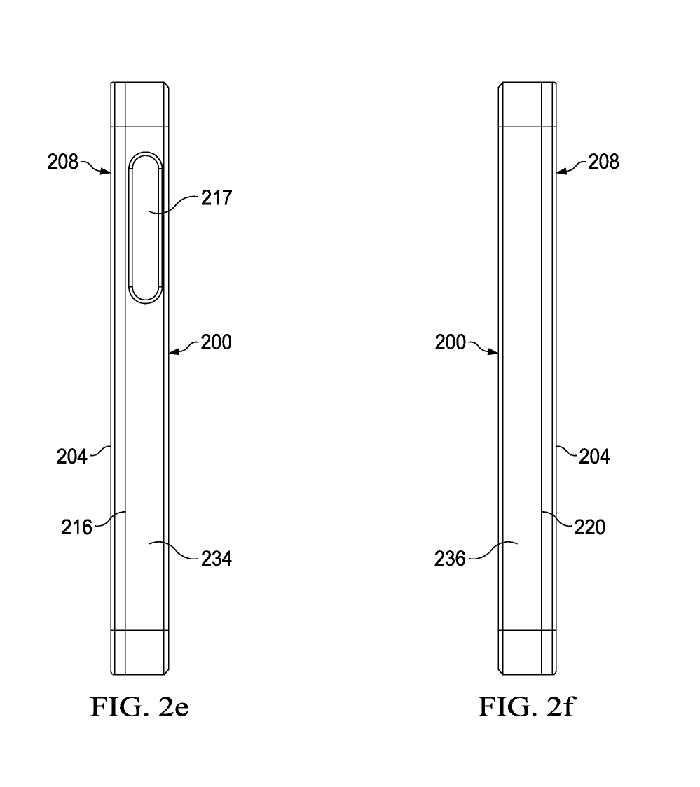

Such an embodiment is illustrated in FIG. 4, which is an orthogonal view looking toward the front of an embodiment of personal electronic device case 400 with reversibly attachable device 440 attached, in its working environment, showing through front face 404 and side face 416 of case 400 an exemplary personal electronic device. In the embodiment of FIG. 4, side 416 of personal electronic device case 400 forms an aperture 417 for access to, in this example, three components of the personal electronic device. Such components might include headphone or earbud jacks, controls, or the like. In this embodiment, the four edges of reversibly attachable article or device 440 are substantially flush with the four edges of personal electronic device case 400. Thus, the exterior configuration of reversibly attachable article or device 440 can preferably be configured to accommodate the purpose and functions of reversibly attachable article or device 440 as well as to accommodate the use of personal electronic device case 400. In one preferred embodiment, personal electronic device case 400 may have strategically placed grips for positioning a user's hand at a location that does not interfere with the operation of reversible attachable device 440 and thus prevents a user's hand from slipping relative to the personal electronic device case 400. Reversibly attachable article or device 440 is easily and comfortably ported and its use is facilitated without any need to unease or unsheathe reversibly attachable article or device 440 from personal electronic device ease 400.

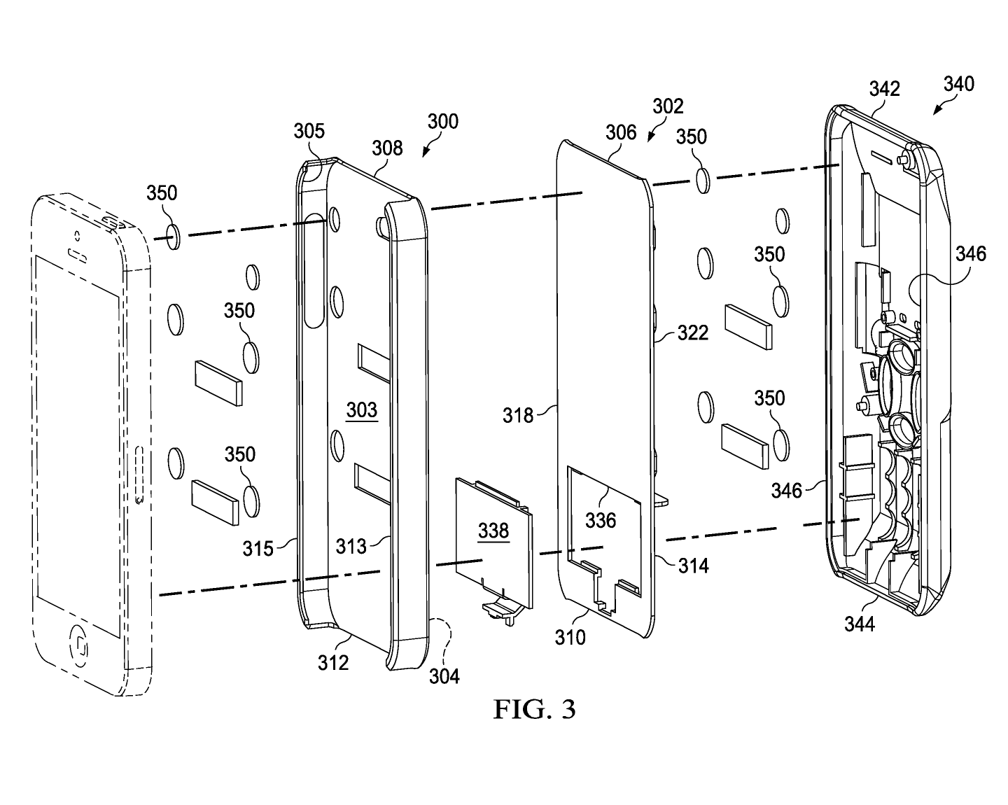

FIG. 5 is a side view showing the back and one side of an embodiment of the personal electronic device case 500 with a reversibly attachable device 540 attached, in their environment, showing through an aperture 517 in the side of the personal electronic device case 500 an exemplary personal electronic device. In this embodiment, reversibly attachable article or device 540 is shown having a length essentially equal to the personal electronic device case 500. All four edges (not shown) of reversibly attachable article or device 540 may extend beyond any or all four edges of personal electronic device case 500. Likewise, all four edges not shown) of reversibly attachable article, or device 540 may not extend to any or all four edges of personal electronic device case 500. Exterior configuration of reversibly attachable article or device 540 is configured to accommodate the purposes and functions of reversibly attachable article or device 540 as well as to accommodate the use of personal electronic device case 500.

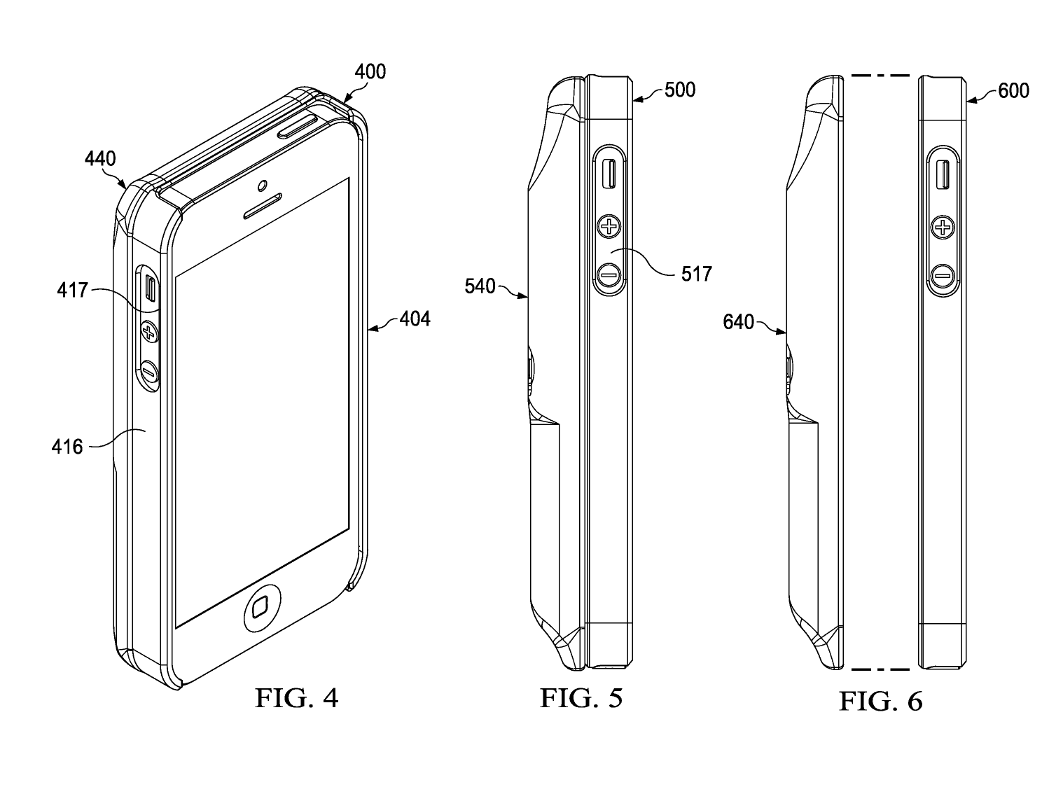

FIG. 6 is a side view of an embodiment that shows a reversibly attachable article or device 640 attached to a back plate (not shown) of the personal electronic device case 600 for reversible attachment and detachment to personal electronic device case 600. Back face 604 (not, shown) and back plate 602 (not shown) are preferably configured to reversibly mate, couple, or adhere to each other by mechanical or other means. In the embodiment shown, magnetic coupling would work. Alternatively, one or the other or both back face 604 (not shown) or back plate 602 (not shown) can be shaped to snap, or reversibly clip to, releasably latch to, connect, fasten, or reversibly lock to the other. Either of back face 604 (not shown) or back plate 602 (not shown), or both may include a material such as one of the components of Velcro®, fibrillar adhesive, microfiber cloth, gecko materials, or adhesive materials, for example. The choice of mating material is made to foster maintenance of the engagement strength between personal electronic device case 600 and reversibly attachable article or device 640 through repeated use and multiple attachments, detachments, and reattachments.

Turning now to FIG. 7, FIG. 7 is an orthogonal view of an embodiment of personal electronic device case 700 showing back face 708 and exterior surface 722 in planar arrangement with reversibly attachable device 740. As shown, reversibly attachable device 740 is a smart key. Exterior surface 734 of major side 716 of personal electronic device case 700 faces the observer. The exterior surface 736 (hidden) of opposed major side 720 (hidden) faces away from the observer.

In accordance with this exemplary embodiment, back plate 708 is configured to reversibly mate to, couple to, adhere to, or attach to an article or device including, as shown for example, a smart key. Reversibly attachable device 740 could include any of the following: a mobile hot spot; a remote control; solar panel; a GoPro® video recorder; a paper notepad; a mini epinephrine pen; an inhaler; a vaporizer; a combination lock; a foldable eyeglasses case; a computer mouse; a finger pad; a Bluetooth® headset holder; an Apple iPod®; an MP3 player; a digital voice, recorder; a shoulder rest; a comb; a GPS device; a satellite communication device; a compass; a whistle; a first aid kit; a data expansion pack; a video game controller; a laser pointer; access key card; cellular signal booster; full range AM/FM transmitter; as pedometer, an accelerometer; a speaker; a flash light; a digital scale; a thermostat; a key slot; a key ring; a toll tag; a pill compartment; a pen; a birth control compartment; an FM transmitter; a magnifying glass or plastic card; a GigaPet®, a card deck holder, a fan that circulates bug repellant or aroma; a baby monitor; a flash drive; a credit card reader: a stylus; a fish eye lens; a heart rate monitor; a glucose meter with lancet and extra test strips; a blood pressure reader; a floating device designed to keep personal electronic device 700 afloat; a Wi-Fi® modem; a projector screen; a bottle opener; a battery pack; pepper spray; a makeup compartment: an Etch-A-Sketch®; a roller maze; a watch face; or a compartment for, for example, a condom, coins, tickets, tampons, earbuds, lip balm, lotion, sunscreen, utility tool, level, band aids, perfume or cologne, sanitizer, contact lenses, cigarettes, lighter, electric cigarettes, flask; breathalyzer, credit cards, business cards, gum, mints, cough drops, measuring tape, mirror, or money clip.

For expedience of disclosure, the embodiments of personal electronic device cases described above and illustrated in the accompanying drawings are discussed in connection with a few personal electronic devices and a few reversibly attachable articles or devices. It is to be understood that this is not meant to in any way limit the application of these inventions to those disclosed devices. For example, related or unrelated devices may also be applicable.

In the foregoing Detailed Description of Exemplary Embodiments, various features are grouped together in a single embodiment for purposes of streamlining the disclosure. This method of disclosure is not to be interpreted as reflecting an intention that any claim requires more features than are expressly recited in each claim. Rather, as the following claims reflect, inventive aspects lie in less than all features of a single foregoing disclosed embodiment,. Thus, the following claims are hereby incorporated into this Description of the Exemplary Embodiments, with each claim standing on its own as a separate embodiment of the invention.

1. A protective case configured to receive a personal electronic device and to magnetically attach to another article, said protective case comprising:
a front face for detachably connecting to a personal electronic device; and
back face comprising at least one magnet for magnetically coupling an article to said protective case.

2. The protective case of claim 1 wherein said article comprises a personal electronic device, a satellite communicator, a credit-card reader, a battery pack, a compartment for storage of a key or credit card, or a decorative back plate.

3. The protective case of claim 1 wherein the attachment includes one or more magnets.

4. A protective case having a front face, a back face and a side face, said case shaped to receive a personal electronic device and to magnetically secure to said back face a back plate.

5. The protective case of claim 4 where said front face is substantially entirely open and configured to secure a personal electronic device and said back plate is configure to reversible secure a second personal electronic device.

6. The protective case of claim 4, further comprising a back plate having a substantially planar surface and configure to receive interchangeable coverings.

7. A protective case configured to receive a personal electronic device and to magnetically attach to another article, said case comprising:
a container for sheathing a personal electronic device, said container configured to retain a smart phone and to reversibly attach to a back plate; and
a back plate configured to reversibly attach to said container.

8. The protective case of claim 7 wherein the back plate is further configured to retain a smart key.

9. The protective case of claim 7 wherein the back plate includes a container.

10. The protective case of claim 7 wherein the back plate includes a surface for receiving images.
